(19) United States
(12) Patent Application Publication
(10) Pub. No.: US 2022/0084991 A1
(43) Pub. Date: Mar. 17, 2022

(54) DISPLAY DEVICE

(71) Applicant: Japan Display Inc., Tokyo (JP)

(72) Inventors: Masanobu IKEDA, Tokyo (JP); Yoshinori AOKI, Tokyo (JP); Akihiro OGAWA, Tokyo (JP)

(73) Assignee: Japan Display Inc., Tokyo (JP)

(21) Appl. No.: 17/463,558

(22) Filed: Sep. 1, 2021

(30) Foreign Application Priority Data
Sep. 11, 2020 (JP) 2020-152738

(51) Int. Cl. H01L 25/075; H01L 27/12; H01L 29/786; H01L 33/58; H01L 33/62; H01L 23/498

(52) U.S. Cl. CPC H01L 25/0753; H01L 27/124; H01L 23/4985; H01L 33/58; H01L 33/62; H01L 29/78633

(57) ABSTRACT

A display device includes a first substrate; a first pixel part provided on the first substrate; a drive circuit provided on the first substrate; a second substrate; a second pixel part provided on the second substrate; and a connecting part electrically connecting the drive circuit to the second pixel part. The first pixel part has pixels each containing a first light-emitting element. The drive circuit is located adjacent to the first pixel part and connected to the first pixel part. The second pixel part has pixels each containing a second light-emitting element and overlaps the drive circuit in a plan view.

### CROSS-REFERENCE TO RELATED APPLICATIONS

This application is based on and claims the benefit of priority from the prior Japanese Patent Application No. 2020-152738, filed on Sep. 11, 2020, the entire contents of which are incorporated herein by reference.

### FIELD

An embodiment of the present invention relates to a display device. In particular, it relates to a display device having an LED (Light Emitting Diode) element in a pixel.

### BACKGROUND

In recent years, as a next-generation display device, LED displays with LED elements mounted on each pixel have been developed. Normally, the LED display has a configuration in which a plurality of LED elements is mounted on a circuit substrate constituting a pixel part. The circuit substrate has a pixel circuit for making the LED element at a position corresponding to each pixel emit light. A method of emitting the LED element of each pixel using the pixel circuit is called an active driving method.

An LED display of the active driving method has a plurality of pixel circuits arranged on a display region, and a driving circuit (e.g., scanning line driving circuit) driving the pixel circuit on a surrounding region (peripheral region) surrounding the display region. In the LED display, a region capable of effectively displaying an image is the display region. The peripheral region where the driving circuit is arranged cannot display an image. Therefore, the conventional LED display has a non-display region surrounding the display region.

When a large screen display is constructed by arranging a plurality of LED displays side by side, the above-mentioned non-display region is viewed as a frame on a grid crossing the screen. Therefore, various technologies for reducing the area of the non-display region have been developed. For example, U.S. Pat. App. Pub. No. 2018/0308832 discloses a technique for constructing a large-screen display using a plurality of LED displays by intentionally arranging a non-display region (such as a scan driving unit) of the LED display in a biased manner to reduce the area of the non-display region arranged between the adjacent LED displays.

### SUMMARY

A display device according to an embodiment of the present invention includes a first substrate; a first pixel part provided on the first substrate; a drive circuit provided on the first substrate; a second substrate; a second pixel part provided on the second substrate; and a connecting part electrically connecting the drive circuit to the second pixel part. The first pixel part has pixels each containing a first light-emitting element. The drive circuit is located adjacent to the first pixel part and connected to the first pixel part. The second pixel part has pixels each containing a second light-emitting element and overlaps the drive circuit in a plan view.

A display device according to an embodiment of the present invention includes a first substrate; a first pixel part provided on the first substrate; a drive circuit provided on the first substrate; a second substrate; and a second pixel part provided on the second substrate. The first pixel part has pixels each containing a first light-emitting element. The drive circuit is located in the vicinity of the first pixel part. The second pixel part has pixels each containing a second light-emitting element and overlaps the drive circuit in a plan view. The first light-emitting element on the first substrate and the second light-emitting element on the second substrate are controlled based on one or more signals output from the drive circuit on the first substrate.

### BRIEF DESCRIPTION OF THE DRAWINGS

FIG. 1 is a plan view of a configuration of a display device according to a first embodiment of the present invention;

FIG. 2 is an enlarged cross-sectional view of a configuration in a vicinity of a connecting part of a display panel according to the first embodiment of the present invention;

FIG. 3 is an enlarged plan view of a configuration in a vicinity of the connecting part of the display panel according to the first embodiment of the present invention;

FIG. 4 is a block diagram of a circuit configuration of the display panel according to the first embodiment of the present invention;

FIG. 5 is a circuit diagram of a configuration of a pixel circuit of the display panel according to the first embodiment of the present invention;

FIG. 6 is a block diagram of a circuit configuration in a vicinity of the connecting part of the display panel according to the first embodiment of the present invention;

FIG. 7 is a block diagram of a circuit configuration in a vicinity of the connecting part of the display panel according to the first embodiment of the present invention;

FIG. 8 is a cross-sectional view of a pixel configuration of the display panel according to the first embodiment of the present invention;

FIG. 9A is a cross-sectional view of a manufacturing process of the display panel according to the first embodiment of the present invention;

FIG. 9B is a cross-sectional view of a manufacturing process of the display panel according to the first embodiment of the present invention;

FIG. 10A is a cross-sectional view of a manufacturing process of the display panel according to the first embodiment of the present invention;

FIG. 10B is a cross-sectional view of a manufacturing process of the display panel according to the first embodiment of the present invention;

FIG. 11 is an enlarged cross-sectional view of a configuration in a vicinity of a connecting part of a display panel according to a second embodiment of the present invention;

FIG. 12 is an enlarged plan view of a configuration in a vicinity of the connecting part of the display panel according to the second embodiment of the present invention;

FIG. 13 is an enlarged cross-sectional view of a configuration in a vicinity of a connecting part of a display panel according to a third embodiment of the present invention;

FIG. 14 is an enlarged plan view of a configuration in a vicinity of the connecting part of the display panel according to the third embodiment of the present invention;

FIG. 15 is an enlarged plan view of a configuration in a vicinity of a connecting part of a display panel according to a fourth embodiment of the present invention;

FIG. 16 is an enlarged cross-sectional view of a configuration in a vicinity of a connecting part of a display panel according to a fifth embodiment of the present invention;

FIG. 17 is a plan view of a configuration of a display device according to a sixth embodiment of the present invention;

FIG. 18 is an enlarged cross-sectional view of a configuration in a vicinity of a connecting part of the display panel according to the sixth embodiment of the present invention; and

FIG. 19 is an enlarged cross-sectional view of a configuration in a vicinity of a connecting part of a display panel according to a seventh embodiment of the present invention.

### DESCRIPTION OF EMBODIMENTS

If a non-display region is biased as in the above-described conventional technology, the area of the non-display region can be reduced in a part of regions of the LED display, but in exchange for this, the area of the non-display region in the other LED display is relatively large. That is, in a method of the conventional technology, there is still a problem that a peripheral region where a driving circuit is arranged becomes dead-space, and it impossible to effectively utilize the size of the LED display.

One of the problems of the present invention is to provide a display device capable of effectively utilizing the peripheral region where the driving circuit is arranged as the display region.

Embodiments of the present invention will be described below with reference to the drawings and the like. However, the present invention can be implemented in various modes without departing from the gist thereof. The present invention is not to be construed as being limited to the description of the following exemplary embodiments. For the sake of clarity of description, the drawings may be schematically represented with respect to widths, thicknesses, shapes, and the like of the respective portions in comparison with actual embodiments. However, the drawings are merely examples and do not limit the interpretation of the present invention.

In describing this embodiment of the present invention, the direction from a substrate to a light-emitting element is “above” and the opposite direction is “below”. However, the expression “above” or “below” merely describes an upper limit relationship of each element. For example, the representation that the light-emitting element is arranged on the substrate also includes cases where other members are interposed between the substrate and the light-emitting element. Furthermore, the terms “above” or “below” include not only the case where the elements overlap in a plan view, but also the case where the elements do not overlap.

In the description of the embodiment of the present invention, components having the same functions as those of the elements already described are denoted by the same reference numerals or the same reference numerals with symbols such as alphabets, and the description thereof is omitted.

In this specification and claims, “display device” refers to a device for displaying an image. That is, “display device” includes not only a display panel or display module, but also a device in which other optical members (e.g., polarized member, touch panel, etc.) are attached to the display panel or display module.

### First Embodiment

### [Configuration of Display Device]

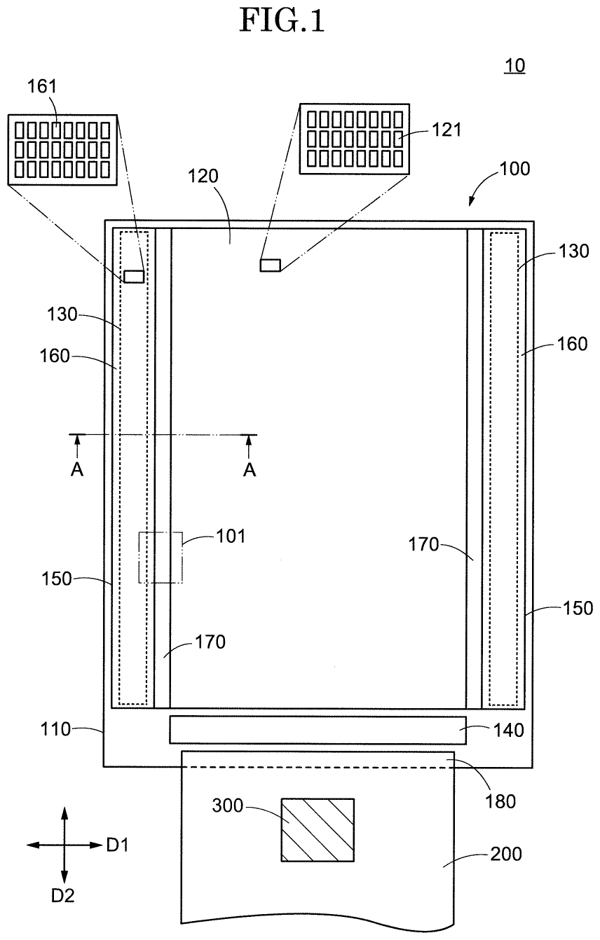

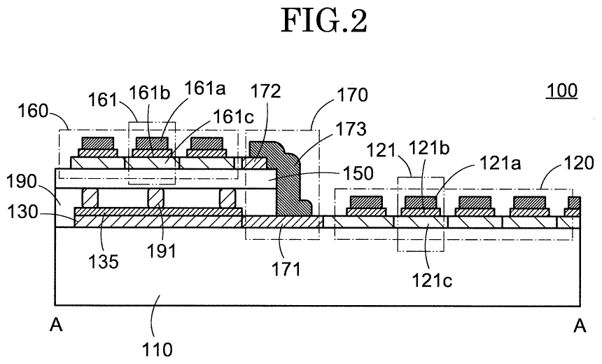

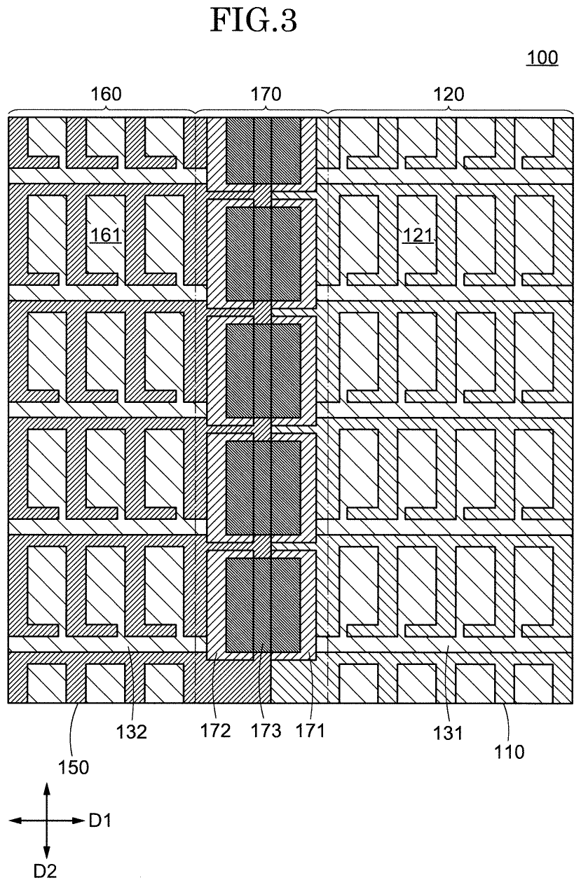

FIG. 1 is a plan view showing a configuration of a display device 10 according to a first embodiment of the present invention. FIG. 2 is an enlarged cross-sectional view showing a configuration in a vicinity of a connecting part 170 in a display panel 100 according to the first embodiment of the present invention. Specifically, FIG. 2 corresponds to a cross-sectional view obtained by cutting the display panel 100 shown in FIG. 1 with A-A line. FIG. 3 is an enlarged plan view showing a configuration in a vicinity of the connecting part 170 in the display panel 100 according to the first embodiment of the present invention. Specifically, FIG. 3 corresponds to a plan view in which a range surrounded by a frame border 101 is enlarged in the display panel 100 shown in FIG. 1.

As shown in FIG. 1, the display device 10 has a display panel 100, a flexible printed circuit board 200 (FPC200), and an integrated circuit 300. The display panel 100 is a display device for displaying an image. The flexible printed circuit board 200 functions as a wiring group that inputs a video signal or control signal transmitted from an external device (not shown) to the display panel 100. The integrated circuit 300 is a signal processing circuit that performs a predetermined signal processing on a video signal and generates a control signal required for display control. Input and output of the signal to the integrated circuit 300 is performed via a wiring provided in the flexible printed circuit board 200.

As shown in FIGS. 1 and 2, the display panel 100 includes a first substrate 110, a first pixel part 120, a gate drive circuit 130, a data drive circuit 140, a second substrate 150, a second pixel part 160, a connecting part 170, and a terminal part 180. However, these elements are examples, and some elements can be omitted. For example, the data drive circuit 140 may be omitted if the integrated circuit 300 has a function equivalent to the data drive circuit 140.

The first substrate 110 functions as a support substrate supporting the first pixel part 120, the gate drive circuit 130, and the data drive circuit 140. As the first substrate 110, a glass substrate, a resin substrate, a ceramic substrate, a metal substrate, or the like can be used. In this embodiment, a glass substrate is used as the first substrate 110. When a resin substrate is used as the first substrate 110, flexibility can be given to the display panel 100.

The first pixel part 120 has a plurality of first pixels 121 arranged in the row direction (D1 direction) and the column direction (D2 direction). In this embodiment, the first pixel 121 is a pixel corresponding to any one of red, green, blue, or white. Each of the plurality of first pixels 121 includes a first light-emitting element 121a. The first light-emitting element 121a is, for example, an LED element. That is, the first light-emitting element 121a is an LED element that emits light in any one of red, green, blue, or white. As shown in FIG. 2, each first light-emitting element 121a is connected to a pixel circuit 121c arranged for each first pixel 121 via a connecting electrode 121b.

As shown in FIG. 1, the gate drive circuit 130 and the data drive circuit 140 are arranged adjacent to the first pixel part 120. The gate drive circuit 130 supplies a gate signal to a gate signal line provided in the first pixel part 120 and the second pixel part 160. The data drive circuit 140 supplies a data signal to a data signal line provided in the first pixel part 120 and the second pixel part 160. In this embodiment, an example in which two gate drive circuits 130 are arranged adjacent to the first pixel part 120 has shown, but not limited to this example, the gate drive circuit 130 may be one.

Similar to the first pixel part 120, the second pixel part 160 has a plurality of second pixels 161 arranged in the row direction (D1 direction) and the column direction (D2 direction). In this embodiment, the second pixel 161 is a pixel corresponding to any one of red, green, blue, or white. Each of the plurality of second pixels 161 includes a second light-emitting element 161a. The second light-emitting element 161a is, for example, an LED element. That is, the second light-emitting element 161a is an LED element that emits light in any one of red, green, blue, or white. As shown in FIG. 2, each second light-emitting element 161a is connected to a pixel circuit 161c arranged for each second pixel 161 via a connecting electrode 161b.

In this embodiment, the second pixel part 160 is arranged above the gate drive circuit 130. That is, as shown in FIG. 1, the second pixel part 160 is arranged to overlap the gate drive circuit 130 at a plan view. In this embodiment, since the gate drive circuits 130 are arranged so as to sandwich the first pixel part 120, two second pixel parts 160 are arranged so as to sandwich the first pixel part 120. The area of the second pixel part 160 is smaller than that of the first pixel part 120. However, by arranging the second pixel part 160 so as to overlap the gate drive circuit 130, in addition to the first pixel part 120, it is possible to display an image even on a peripheral region where the gate drive circuit 130 is arranged.

In this embodiment, the second pixel part 160 is supported by the second substrate 150. That is, the second substrate 150 functions as a support substrate of the second pixel part 160. The second substrate 150 is adhered onto the gate drive circuit 130 using an adhesive layer 190. That is, the adhesive layer 190 is arranged between the gate drive circuit 130 and the second pixel part 160. In this embodiment, a spacer 191 is arranged in the adhesive layer 190. The spacer 191 functions to hold an interval between the second pixel part 160 and the first substrate 110 or the gate drive circuit 130. However, the present invention is not limited to this example, and the spacer 191 can be omitted by holding the interval by using the adhesive layer 190.

Furthermore, in this embodiment, a shield layer 135 for reducing noises due to coupling is arranged between the gate drive circuit 130 and the second pixel part 160. As the shield layer 135, a conductive layer made of a metal material or metal oxide material can be used. In this embodiment, to form the shield layer 135 simultaneously with the formation of the connecting electrode 121b in the first pixel part 120, the shield layer 135 and the connecting electrode 121b are made of the same metal material. However, the present invention is not limited to this example, and the shield layer 135 may be made of a conductive layer made of another metal material or metal oxide material used in the process of forming the pixel circuit 121c. The shield layer 135 is preferably electrically connected to, for example, a cathode power line and held at a fixed potential. If the shield layer 135 is formed of a light-shielding metal material, it is possible to shield a light from the second light-emitting element 161a toward the gate drive circuit 130. As a result, it is possible to suppress problems such as malfunction of the gate drive circuit 130 due to the irradiation of the second light-emitting element 161a.

In this embodiment, the thickness of the second substrate 150 is desirably thinner than the thickness of the first substrate 110. For example, the thickness of the second substrate 150 is preferably ⅕ or less (preferably 1/10 or less) of the thickness of the first substrate 110. By making the thickness of the second substrate 150 relatively thinner than the thickness of the first substrate 110, it is possible to make the step formed by the second substrate 150 and the second pixel part 160 between the first pixel part 120 and the second pixel part 160 inconspicuous.

The second pixel part 160 is electrically connected to the gate drive circuit 130 via the connecting part 170. The second pixel part 160 is electrically connected to the first pixel part 120 via the connecting part 170. The gate signal output from the gate drive circuit 130 is transmitted to both the first pixel part 120 and the second pixel part 160.

As shown in FIGS. 2 and 3, the connecting part 170 includes a first pad 171, a second pad 172, and a conductive member 173. The first pad 171 is an electrode arranged between the first pixel part 120 and the gate drive circuit 130. The second pad 172 is an electrode arranged adjacent to the second pixel part 160. The conductive member 173 electrically connects the first pad 171 and the second pad 172. In this embodiment, a member in which a black conductive material such as carbon black is contained in a resin material is used as the conductive member 173.

As shown in FIGS. 2 and 3, the conductive member 173 is arranged on the side surface of the second substrate 150 (strictly, the second substrate 150 and the adhesive layer 190) so that the D2 direction is longitudinal. As shown in FIG. 3, the conductive member 173 is arranged between the first pixel 121 and the second pixel 161. Therefore, when a black member is used as the conductive member 173, the light emitted from the second light-emitting element 161a to the transverse direction (D1 direction) can be prevented from traveling to the first pixel part 120 through the side surface of the second substrate 150. Similarly, when a black member is used as the conductive member 173, the light emitted from the first light-emitting element 121a to the transverse direction (D1 direction) can be prevented from traveling to the second pixel part 130 through the side surface of the second substrate 150.

As shown in FIG. 3, a first gate signal line 131 electrically connected to each of the first pixels 121 is connected to each of the first pads 171. A second gate signal line 132 electrically connected to each of the second pixels 161 is connected to each of the second pads 172. That is, in the display device 10 of this embodiment, the first gate signal line 131 and the second gate signal line 132 are electrically connected one-to-one via the connecting part 170. Specifically, the Nth (N is a natural number) gate signal line in a plurality of first gate signal lines 131 and the Nth (N is a natural number) gate signal line in a plurality of second gate lines 132 are electrically connected.

As described above, in the display device 10 of this embodiment, in addition to the first pixel part 120, the second pixel part 160 arranged to overlap the gate drive circuit 130 can also function as an image display region. That is, the display device 10 of this embodiment can effectively utilize the peripheral region that was a dead space as the display region.

### [Circuit Configuration of Display Panel]

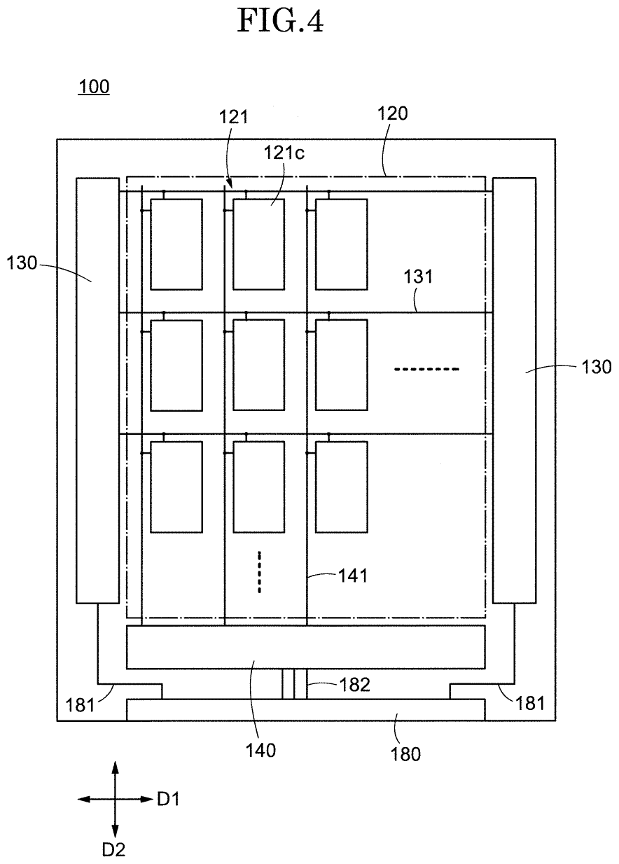

FIG. 4 is a block diagram showing a circuit configuration of the display panel 100 according to the first embodiment of the present invention. However, FIG. 4 is not shown for the second pixel part 160 and the connecting part 170 for simplicity of explanation.

A plurality of pixel circuits 121c is arranged in a region corresponding to the first pixel part 120. Each of the pixel circuits 121c is a circuit for making each first light-emitting element 121a emit light. Each pixel circuit 121c is arranged corresponding to each first pixel 121. That is, in the first pixel part 120, the plurality of pixel circuits 121c is arranged in the row direction (D1 direction) and the column direction (D2 direction). The gate drive circuit 130 is arranged at a position adjacent to the first pixel part 120 in the row direction (D1 direction). The data drive circuit 140 is arranged at a position adjacent to the first pixel part 120 in the column direction (D2 direction).

The plurality of first-gate signal lines 131 is connected to the gate drive circuit 130. A plurality of first data signal lines 141 is connected to the data drive circuit 140. The first gate signal lines 131 and the first data signal lines 141 are provided in the first pixel part 120. The pixel circuit 121c is provided at a position where the first gate signal line 131 and the first data signal line 141 cross each other, and is electrically connected to the first gate signal line 131 and the first data signal line 141. In FIG. 4, only the first gate signal line 131 and the first data signal line 141 are shown as the signal line for the sake of simplicity, but in reality, other signal lines are provided depending on the configuration of the pixel circuit 121c.

The terminal part 180 is electrically connected to the gate drive circuit 130 via a connecting wiring 181 and to the data drive circuit 140 via a connecting wiring 182. As described with reference to FIG. 1, the flexible printed circuit board 200 is connected to the terminal part 180. Therefore, the control signal and video signal input via the flexible printed circuit board 200 are input to the gate drive circuit 130 or the data drive circuit 140 via the connecting wirings 181 and 182.

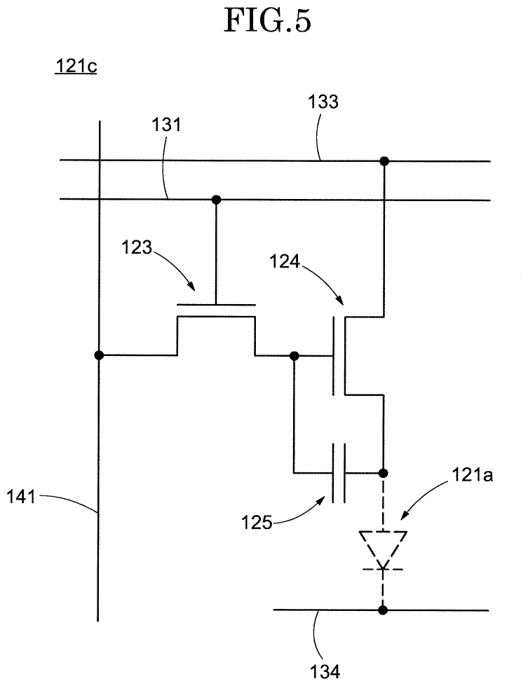

A specific circuit configuration of the pixel circuit 121c shown in FIG. 4 will be described here. FIG. 5 is a circuit diagram showing a configuration of the pixel circuit 121c in the display panel 100 according to the first embodiment of the present invention. The pixel circuit 121c includes a part of the first gate signal line 131, a part of the first data signal line 141, a part of an anode power line 133, a part of a cathode power line 134, a select transistor 123, a drive transistor 124, and a storage capacity 125. Actually, the first light-emitting element 121a is connected between the drive transistor 124 and the cathode power line 134 in the pixel circuit 121c. However, in FIG. 5, since the first light-emitting element 121a is an element connected to the pixel circuit 121c and is not an element constituting the pixel circuit 121c, the first light-emitting element 121a is illustrated by a dotted line. The pixel circuit 121c shown in FIG. 5 is merely an example, and may have another circuit configuration.

As shown in FIG. 5, a gate terminal of the select transistor 123 is connected to the first gate signal line 131. A source terminal of the select transistor 123 is connected to the first data signal line 141, and a drain terminal of the select transistor 123 is connected to a gate terminal of the drive transistor 124, respectively. However, the source terminal and drain terminal of the select transistor 123 may interchange each other depending on the potential difference between the source and drain of the select transistor 123.

In this embodiment, the drive transistor 124 is an N-channel transistor. Therefore, the source terminal and drain terminal of the drive transistor 124 are connected to the first light-emitting element 121a and the anode power line 133, respectively. The storage capacity 125 is connected between the gate terminal and source terminal of the drive transistor 124. That is, the storage capacity 125 is also connected to the drain terminal of the select transistor 123. The anode terminal of the first light-emitting element 121a is connected to the anode power line 133 via the drive transistor 124. The cathode terminal of the first light-emitting element 121a is connected to the cathode power line 134.

The first data signal line 141 is supplied with a data signal (gray-scale signal) for determining the emission intensity of the first light-emitting element 121a. Since the data signal is a signal corresponding to the image to be displayed, it is also referred to as an image signal or a video signal. The first gate signal line 131 is provided with a gate signal for selecting the select transistor 123 to write the data signal. When the select transistor 123 is turned on, the data signal input from the first data signal line 141 is held in the storage capacity 125. Thereafter, when the drive transistor 124 is turned on, a driving current corresponding to the data signal flows between the drain terminal and source terminal of the drive transistor 124. When the driving current output from the source terminal of the drive transistor 124 is input to the first light-emitting element 121a, the first light-emitting element 121a emits light with the emission intensity corresponding to the data signal.

As described above, in the display device 10 of this embodiment, the second pixel part 160 having the plurality of second pixels 161 is arranged above the gate drive circuit 130. Each pixel circuit 161c has the same circuit configuration as that of the pixel circuit 121c described above (that is, the circuit configuration shown in FIG. 5). Therefore, in this embodiment, it is necessary to supply the gate signal and the data signal to the second pixel 161 in addition to the first pixel 121.

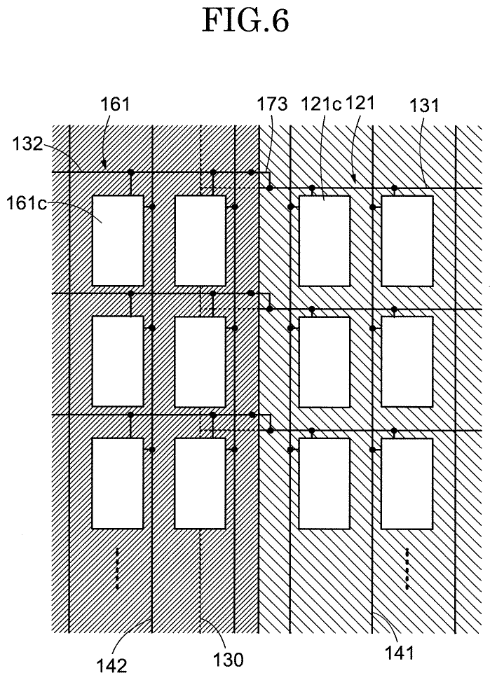

FIG. 6 is a block diagram showing a circuit configuration in a vicinity of the connecting part 170 in the display panel 100 according to the first embodiment. Specifically, FIG. 6 shows the connection between the pixel circuit 161c and the gate drive circuit 130 in the second pixel 161. As shown in FIG. 6, the first gate signal line 131 connected to the gate drive circuit 130 is electrically connected to the second gate signal line 132 via the conductive member 173. Therefore, for example, the gate signal output from the gate drive circuit 130 to the Nth first gate signal line 131 is also transmitted to the second gate signal line 132 connected to the first gate signal line 131. That is, the plurality of first pixels 121 connected to the Nth first gate signal line 131 and the plurality of second pixels 161 connected to the Nth second gate 132 are controlled as pixels located in the same row. As described above, in this embodiment, the gate drive circuit 130 supplies the gate signal for both the first pixel part 120 and the second pixel part 160.

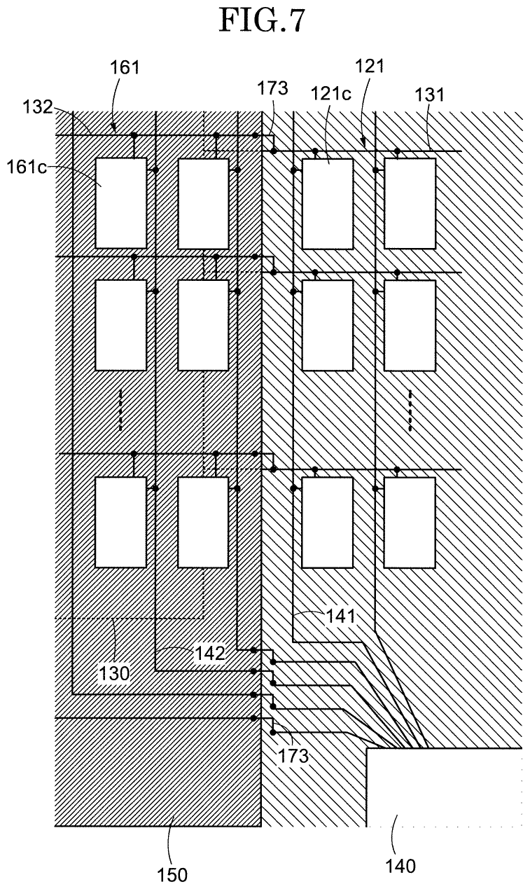

FIG. 7 is a block diagram showing a circuit configuration in a vicinity of the connecting part 170 in the display panel 100 according to the first embodiment of the present invention. Specifically, FIG. 7 shows the connection between the pixel circuit 161c and the data drive circuit 140 of the second pixel 161. As shown in FIG. 7, a part of the first data signal line 141 connected to the data drive circuit 140 is connected to the pixel circuit 121c of the first pixel 121. On the other hand, other parts of the first data signal line 141 are electrically connected to the second data 142 via the conductive member 173. The second data signal line 142 is connected to the pixel circuit 161c of the second pixels 161. As described above, in this embodiment, the data drive circuit 140 supplies the data signal for both the first pixel part 120 and the second pixel part 160.

### [Cross-Sectional Structure of Pixel]

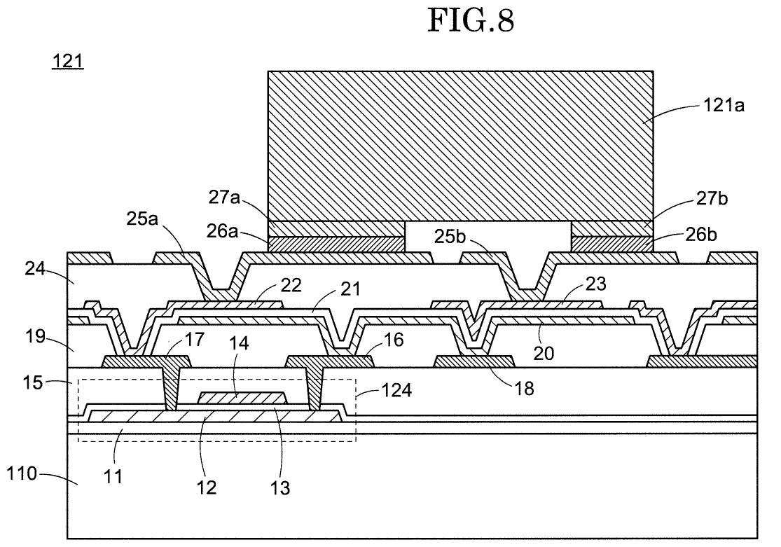

FIG. 8 is a cross-sectional view showing a configuration of a pixel in the display panel 100 according to the first embodiment of the present invention. In this embodiment, the pixel structure of the display panel 100 will be described by exemplifying the first pixel 121. Since the cross-sectional structure of the second pixel 161 is the same as the cross-sectional structure of the first pixel 121, a description of the second pixel 161 will be omitted. As shown in FIG. 5, although the pixel circuit 121c having a plurality of transistors is arranged in the first pixel 121, a description of some elements is omitted to simplify the description.

The base layer 11 is provided on the first substrate 110. The base layer 11 is a silicon oxide layer, a silicon nitride layer, or an insulating layer obtained by stacking them. The base layer 11 functions as a barrier layer that prevents an alkaline component or the like from entering from the first substrate 110. The drive transistor 124 (see FIG. 5) is provided on the first substrate 110.

The drive transistor 124 includes a semiconductor layer 12, a gate insulating layer 13 and a gate electrode 14. A source electrode 16 and a drain electrode 17 are connected to the semiconductor layer 12 via an insulating layer 15. The source electrode 16 and the drain electrode 17 function as the source terminal and drain terminal of the drive transistor 124, respectively. Although not shown, as shown in FIG. 5, the gate electrode 14 is connected to the drain terminal of the select transistor 123.

A wiring 18 is provided in the same layer as the source electrode 16 and the drain electrode 17. The wiring 18 functions as the anode power line 133 shown in FIG. 5. Therefore, the source electrode 16 and the wiring 18 are electrically connected by a connecting wiring 20 provided on a planarizing layer 19. The planarizing layer 19 is a transparent resin layer using a resin material such as polyimide or acrylic. The connecting wiring 20 is a transparent conductive layer using a metal oxide material such as an ITO (Indium Tin Oxide). However, the present invention is not limited to this example, and other metal materials may be used as the connecting wiring 20.

An insulating layer 21 made of silicon nitride or the like is provided on the connecting wiring 20. An anode electrode 22 and a cathode electrode 23 are provided on the insulating layer 21. In this embodiment, the anode electrode 22 and the cathode electrode 23 are transparent conductive layers using a metal oxide material such as an ITO. The anode electrode 22 is connected to the drain electrode 17 via an opening provided in the planarizing layer 19 and the insulating layer 21.

The anode electrode 22 and the cathode electrode 23 are connected to mounting pads 25a and 25b via a planarizing layer 24, respectively. The mounting pads 25a and 25b are made of, for example, a metal material such as tantalum or tungsten. Connecting electrodes 26a and 26b are provided on the mounting pads 25a and 25b, respectively. In this embodiment, electrodes made of tin (Sn) are arranged as the connecting electrodes 26a and 26b. The connecting electrodes 26a and 26b shown in FIG. 8 correspond to the connecting electrode 121b shown in FIG. 2.

Terminal electrodes 27a and 27b of the first light-emitting element 121a are joined to the connecting electrodes 26a and 26b, respectively. In this embodiment, the terminal electrodes 27a and 27b are electrodes made of gold. The terminal electrodes 27a and 27b may be made of silver (Ag).

As shown in FIG. 5, the first light-emitting element 121a is connected between the drain terminal of the drive transistor 124 and the cathode power line 134. That is, the terminal 27a of the first light-emitting element 121a is connected to the anode electrode 22 connected to the drain electrode 17 of the drive transistor 124. The terminal electrode 27b of the first light-emitting element 121a is connected to the cathode electrode 23. Although not shown in FIG. 8, as shown in FIG. 5, the cathode electrode 23 is electrically connected to the cathode power line 134.

In this embodiment, an example in which a flip-chip type LED element is used as the first light-emitting element 121a has been described. The flip-chip type LED element has a structure in which the terminal electrodes connected to each of an n-type semiconductor and a p-type semiconductor are arranged in the same direction (in the example shown in FIG. 8, the direction toward the first substrate 110). However, the present invention is not limited to this example, and a face-up type LED element may be used as the first light-emitting element 121a. The face-up type LED element has a structure with an anode electrode (or cathode electrode) on the side close to the support substrate and a cathode electrode (or anode electrode) on the side far from the support substrate. In other words, the face-up type LED element has a structure in which a semiconductor layer is sandwiched between the anode electrode and the cathode electrode.

### [Manufacturing Process of Display Device]

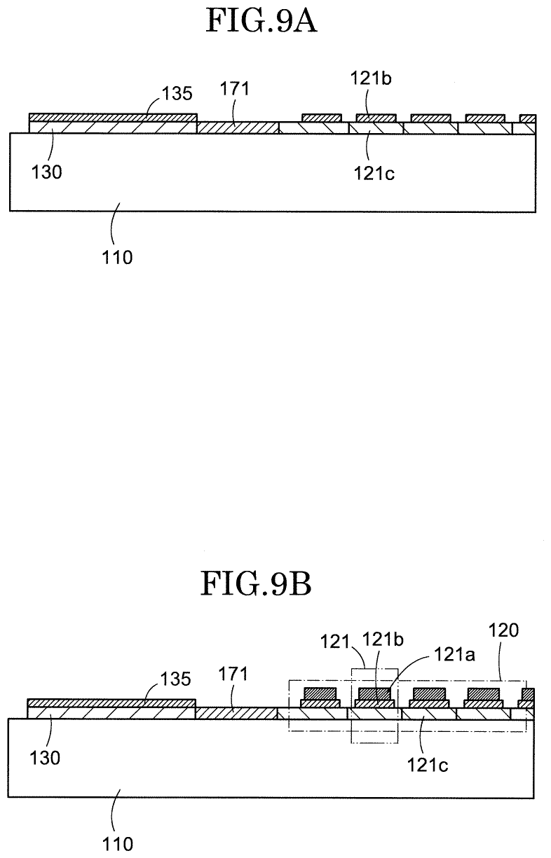

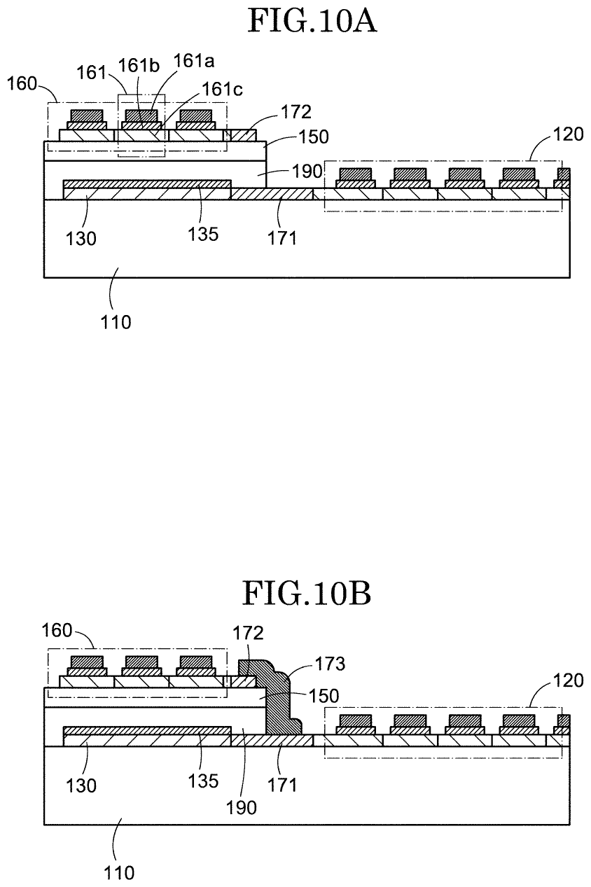

FIG. 9A, FIG. 9B, FIG. 10A and FIG. 10B are cross-sectional views showing a manufacturing process of the display panel 100 according to the first embodiment.

First, as shown in FIG. 9A, the pixel circuit 121c, the first pad 171, and the gate drive circuit 130 are formed on the first substrate 110. The pixel circuit 121c and the gate drive circuit 130 may be formed using a transistor formed using a known thin film forming technique. Although not shown, the data drive circuit 140 and the terminal part 180 or the like are also formed on the first substrate 110. The connecting electrode 121b is formed on the pixel circuit 121c. The shield layer 135 is formed on the gate drive circuit 130 at the same time as the formation of the connecting electrode 121b.

Next, as shown in FIG. 9B, the first light-emitting element 121a is arranged on the connecting electrode 121b. In this embodiment, a laser beam is irradiated on each connecting electrode 121b with each first light-emitting element 121a mounted thereon, and the connecting electrode 121b, and the terminal electrodes 27a and 27b of the first light-emitting element 121a (see FIG. 8) are joined. In this embodiment, since a constituent material of the connecting electrode 121b is tin, and a constituent material of the terminal electrodes 27a and 27b is gold, a eutectic alloy made of tin and gold is formed on the joint. In this embodiment, the connecting electrode 121b and the terminal electrodes 27a and 27b are firmly joined by the eutectic alloy. Thus, it is possible to form the first pixel part 120 having the plurality of first pixels 121.

Next, as shown in FIG. 10A, the second pixel part 160 and the second pad 172 are adhered onto the gate drive circuit 130. Specifically, the second substrate 150 is adhered onto the gate drive circuit 130 via the adhesive layer 190. In this embodiment, a thermosetting resin is used as the adhesive layer 190. At this time, at least a part of the first pad 171 is exposed on the first substrate 110.

Next, as shown in FIG. 10B, the conductive member 173 is formed to electrically connect the first pad 171 and the second pad 172. There is no particular limitation on the method of forming the conductive member 173, but it is preferable to use a method of locally applying a small amount of a liquid containing a conductive material. Examples of such a method include a dispenser method, an inkjet method, an electrostatic coating method, and the like. As described above, by using a technique of applying a conductive material to the locally targeted portion, it is possible to form the conductive member 173 with a high degree of freedom. In the above method, the display device 10 described with reference to FIG. 2 can be formed.

### Second Embodiment

In this embodiment, an example of electrically connecting the gate drive circuit 130 and the second pixel part 160 in a method different from the first embodiment will be described. Specifically, in the display panel 100 of this embodiment, a conductive member 173a included in a connecting part 170a penetrates a second substrate 150a. In this embodiment, portions different from those of the first embodiment will be described. In the drawings used in the description of this embodiment, the same components as those of the first embodiment are denoted by the same reference numerals, and detailed description thereof is omitted.

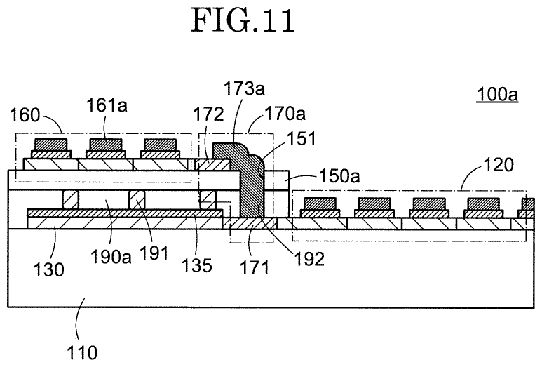

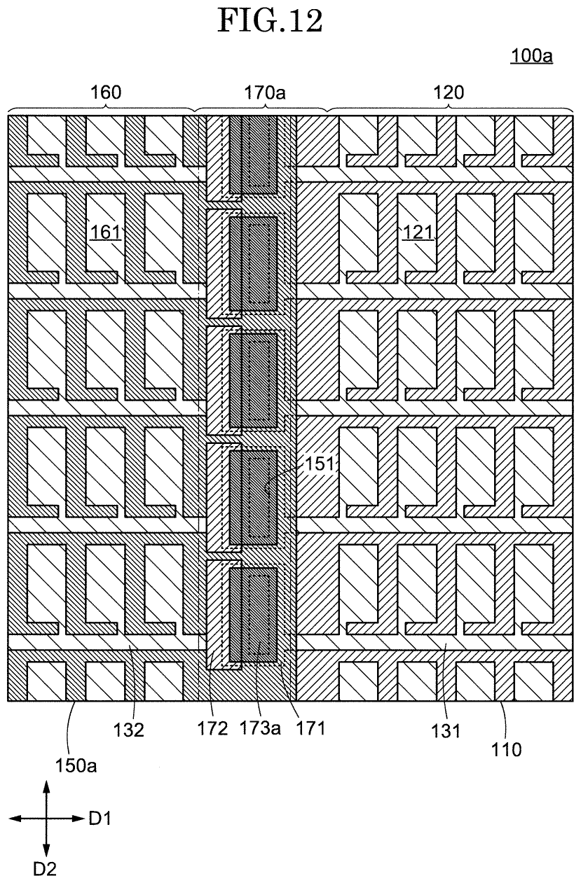

FIG. 11 is an enlarged cross-sectional view showing a configuration in a vicinity of the connecting part 170a in a display panel 100a according to a second embodiment. FIG. 12 is an enlarged plan view showing a configuration in a vicinity of the connecting part 170a in the display panel 100a according to the second embodiment. As shown in FIG. 11, the conductive member 173a of this embodiment penetrates the second substrate 150a and an adhesive layer 190a when electrically connecting the first pad 171 and the second pad 172. That is, the conductive member 173a is connected to the first pad 171 and the second pad 172 via openings 151 and 192 provided in the second substrate 150a and the adhesive layer 190a, respectively.

In this embodiment, both the second substrate 150a and the adhesive layer 190a are made of a resin material. Therefore, after the second substrate 150a is adhered to using the adhesive layer 190a, the opening 151 and the opening 192 can be formed by, for example, irradiation with a laser beam. After the opening 151 and the opening 192 are formed, the conductive member 173a may be formed by the same method as that of the first embodiment (e.g., the dispenser method).

As shown in FIG. 12, the conductive member 173a is arranged between the first pixel 121 and the second pixel 161 so that the D2 direction is the longitudinal direction. Therefore, when a black member is used as the conductive member 173a, the light emitted from the second light-emitting element 161a to the transverse direction (D1) can be prevented from traveling to the first pixel part 120. However, a conductive member 173b does not have to be black.

### Third Embodiment

In this embodiment, an example of electrically connecting the gate drive circuit 130 and the second pixel part 160 in a method different from the first embodiment will be described. Specifically, in the display panel 100 of this embodiment, the first pad 171 and the second pad 172 are arranged to face each other, and the first pad 171 and the second pad 172 are electrically connected by the conductive member 173b. In this embodiment, portions different from those of the first embodiment will be described. In the drawings used in the description of this embodiment, the same components as those of the first embodiment are denoted by the same reference numerals, and detailed description thereof is omitted.

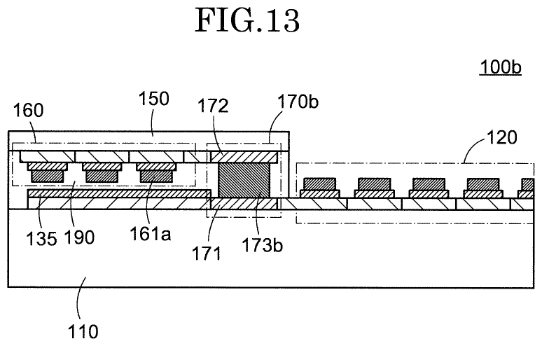

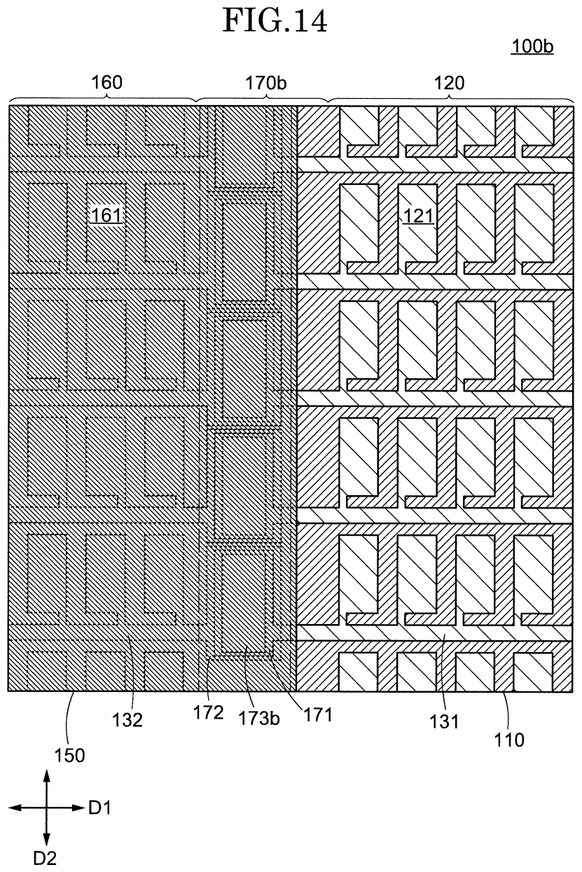

FIG. 13 is an enlarged cross-sectional view showing a configuration in a vicinity of the connecting part 170a in a display panel 100b according to a third embodiment. FIG. 14 is an enlarged plan view showing a configuration in a vicinity of a connecting part 170b in the display panel 100b according to the third embodiment. As shown in FIG. 13, in this embodiment, the positional relation between the second substrate 150 and the second pixel part 160 is opposite to that in the first embodiment. In other words, in the display panel 100b of this embodiment, the first pad 171 and the second pad 172 are arranged to face each other. Then, the conductive member 173b is arranged between the first pad 171 and the second pad 172. As a result, it is possible to electrically connect the gate drive circuit 130 and the second pixel part 160.

The conductive member 173b may be formed in the same method as the first embodiment and the second embodiment (for example, the dispenser method). In this embodiment, forming the conductive member 173b on the first pad 171 in advance. Thereafter, the adhesive layer 190 is provided on the gate drive circuit 130 and around the conductive member 173b. After the adhesive layer 190 is provided, the positions of the first substrate 110 and the second substrate 150 are aligned so that the positions of the first pad 171 and second pad 172 overlap. After the first substrate 110 and the second substrate 150 are aligned, bonding the first substrate 110 and the second substrate 150 each other via the adhesive layer 190. At this time, the first pad 171 and the second pad 172 are electrically connected via the conductive member 173b.

As shown in FIG. 14, the conductive member 173b is arranged between the first pixel 121 and the second pixel 161 so that the D2 direction is the longitudinal direction. Therefore, when a black member is used as the conductive member 173b, the light emitted from the second light-emitting element 161a to the transverse direction (D1 direction) can be prevented from traveling to the first pixel part 120. However, the conductive member 173b does not have to be black.

In this embodiment, the light output from the second light-emitting element 161a is emitted through the second substrate 150. That is, a light-emitting surface of the second light-emitting element 161a of this embodiment is opposite to a light-emitting surface of the second light-emitting element 161a of the first embodiment. However, the present invention is not limited to this example, and the second light-emitting element 161a having the same configuration as that of the first embodiment may be used. In this case, by forming the shield layer 135 located below the second light-emitting element 161a with a metal material, the shield layer 135 may be used as a reflective member.

### Fourth Embodiment

In this embodiment, an example of a display panel 100c having a first pixel part 120c and a second pixel part 160c that is different from the first embodiment will be described. Specifically, in the display panel 100c of this embodiment, the first pixel part 120c and the second pixel part 160c are provided with a first light-shielding layer 31 and a second light-shielding layer 32, respectively. In this embodiment, portions different from those of the first embodiment will be described. In the drawings used in the description of this embodiment, the same components as those of the first embodiment are denoted by the same reference numerals, and detailed description thereof is omitted.

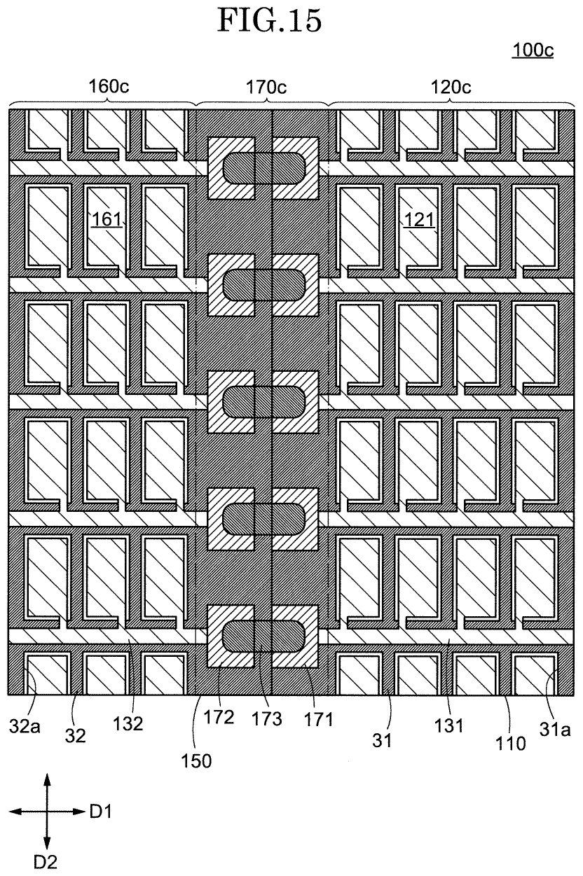

FIG. 15 is an enlarged plan view showing a configuration in a vicinity of a connecting part 170c in the display panel 100c according to a fourth embodiment. As shown in FIG. 15, the display panel 100c of this embodiment has the first light-shielding layer 31 in the first pixel part 120c. The first light-shielding layer 31 has an opening 31a at a position corresponding to the first light-emitting element 121a (in other words, at a position corresponding to the first pixel 121).

The first light-shielding layer 31 may be formed using a resin layer containing, for example, a black pigment. That is, the first light-shielding layer 31 is an insulating black member. As a result, in the display panel 100c of this embodiment, a region other than the first pixel 121 in the first pixel part 120c functions as a region that absorbs light.

Similar to the first pixel part 120c, the second pixel part 160c has the second light-shielding layer 32. The second light-shielding layer 32 has an opening 32a at a position corresponding to the second light-emitting element 161a (in other words, at a position corresponding to the second pixel 161). Even in this case, a region other than the second pixel 161 in the second pixel part 160c functions as a region that absorbs light.

As described above, the display panel 100c of this embodiment has the first light-shielding layer 31 and the second light-shielding layer 32 that absorb light in the first pixel part 120c and the second pixel part 160c. Therefore, the first pixel part 120c and the second pixel part 160c can absorb the light entered from the outside. This makes it possible to make the step formed by the second substrate 150 and the second pixel part 160c inconspicuous. A contrast can be improved when displaying images by suppressing the light reflected in the region other than the pixels.

### Fifth Embodiment

In this embodiment, an example of a display panel 100d having a second pixel part 160d that is different from the first embodiment will be described. Specifically, in the display panel 100d of this embodiment, a part of the second pixel part 160d is curved. In this embodiment, portions different from those of the first embodiment will be described. In the drawings used in the description of this embodiment, the same components as those of the first embodiment are denoted by the same reference numerals, and detailed description thereof is omitted.

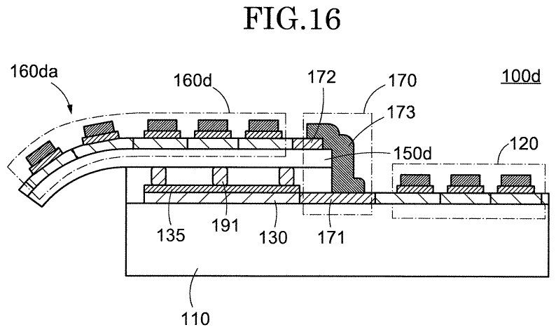

FIG. 16 is an enlarged cross-sectional view showing a configuration in a vicinity of the connecting part 170 in the display panel 100d according to a fifth embodiment. In this embodiment, a substrate made of a resin material is used as a second substrate 150d for supporting the second pixel part 160d. That is, the second substrate 150d is a flexible substrate having flexibility. Therefore, in this embodiment, by using the flexibility of the second substrate 150d, a part of the second substrate 150d (specifically, a part that does not overlap with the first substrate 110 in a plan view) can be curved.

Similar to the first embodiment, the thickness of the second substrate 150d is desirably thinner than the thickness of the first substrate 110. For example, the thickness of the second substrate 150d is preferably ⅕ or less (preferably 1/10 or less) of the thickness of the first substrate 110. By making the thickness of the second substrate 150d relatively smaller than the thickness of the first substrate 110, it is possible to make the step formed by the second substrate 150d and the second pixel part 160d, that is, the step between the first pixel part 120 and the second pixel part 160d, inconspicuous.

As shown in FIG. 16, in the display panel 100d of this embodiment, since the second substrate 150d is curved in a plan view, the second pixel part 160d supported by the second substrate 150d is also curved. Although not shown in FIG. 16, similar to the first embodiment, the display panel 100d has the second pixel part 160d so as to sandwich the first pixel part 120. That is, the display panel 100d of this embodiment has a curved part 160da at the end of the screen on the side where the gate drive circuit 130 is arranged and can display an image also on the curved part 160da.

### Sixth Embodiment

In this embodiment, an example of a display device having a composite screen in which a plurality of display panels is connected will be described. Specifically, in a display panel 100e of this embodiment, a first display panel 100-1 and a second display panel 100-2 are connected to form the horizontally long display panel 100e. In this embodiment, portions different from those of the first embodiment will be described. In the drawings used in the description of this embodiment, the same components as those of the first embodiment are denoted by the same reference numerals, and detailed description thereof is omitted.

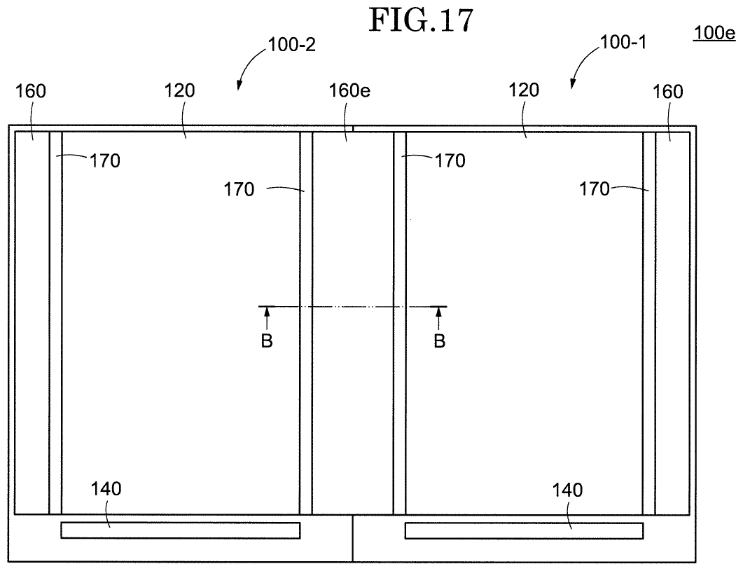

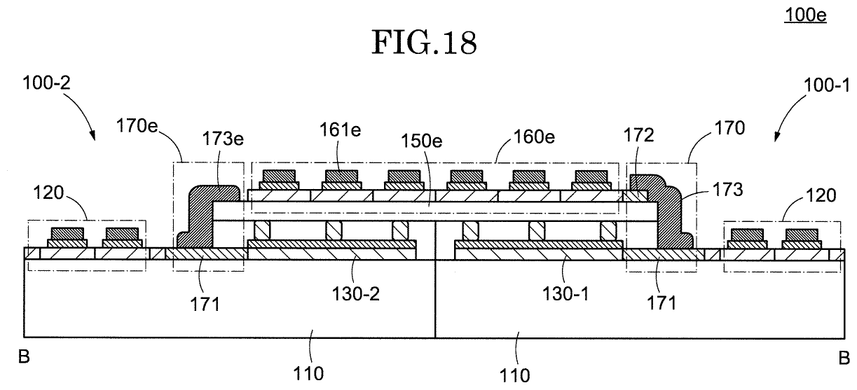

FIG. 17 is a plan view showing a configuration of a display panel 100e according to a sixth embodiment of the present invention. FIG. 18 is an enlarged cross-sectional view showing a configuration in the vicinity of a connecting portion in the display panel 100e according to the sixth embodiment. Specifically, FIG. 18 corresponds to a cross-sectional view in which the display panel 100e shown in FIG. 17 is cut along B-B line.

As shown in FIG. 17, the display panel 100e of this embodiment has a configuration in which the first display panel 100-1 and the second display panel 100-2 are connected with their long sides facing each other. In this embodiment, the display panel 100e has a second pixel part 160e over the first display panel 100-1 and the second display panel 100-2. That is, the display panel 100e is configured to share one second pixel part 160e with a plurality of display panels (specifically, the first display panel 100-1 and the second display panel 100-2). However, in this embodiment, an example in which two display panels are connected is shown, the present invention is not limited to this example, and the number of display panels to be connected is not limited.

As shown in FIG. 18, each of the first display panel 100-1 and the second display panel 100-2 has the same configuration as that of the first embodiment. The difference from the first embodiment is that the second pixel part 160e is provided over the first display panel 100-1 and the second display panel 100-2. Therefore, the display panel 100e of this embodiment can display an image by the second pixel part 160e even in the connecting portion between the first display panel 100-1 and the second display panel 100-2.

The display panel 100e of this embodiment is further different from the first embodiment in that a connecting part 170e of the second display panel 100-2 does not have the second pad. That is, in this embodiment, the second pixel part 160e is electrically connected to a gate drive circuit 130-1, but is not electrically connected to a gate drive circuit 130-2. In this embodiment, an example in which the second pad is omitted from the connecting part 170e in the second display panel 100-2 has shown, the present invention is not limited to this, and a conductive member 173e may be changed to an insulating member.

The display panel 100e of this embodiment supplies the gate signal from the gate drive circuit 130-1 to a plurality of second pixels 161e arranged in the second pixel part 160e. Similar to the first embodiment, the gate drive circuit 130-1 and the second pixel part 160e are electrically connected via the connecting part 170. At this time, since the gate drive circuit 130-2 is not electrically connected to the second pixel part 160e, the gate drive circuit 130-2 supplies the gate signal only to the first pixel part 120 of the second display panel 100-2.

In this embodiment, the connecting part 170e arranged in the second display panel 100-2 is used to fix a second substrate 150e. That is, the conductive member 173e of the connecting part 170e functions as a fixing member for fixing the first substrate 110 and the second substrate 150e of the second display panel 100-2. According to this embodiment, it is possible to connect the first display panel 100-1 and the second 100-2 without a gap. Further, according to this embodiment, the second pixel part 160e can be firmly supported by the connecting part 170 of the first display panel 100-1 and the connecting part 170e of the second display panel 100-2.

In this embodiment, an example in which the connecting part 170e of the second display panel 100-2 is used as the fixing member has shown, the present invention is not limited to this example. For example, the second pad 172 may be provided for the connecting part 170e, and the gate drive circuit 130-2 and the second pixel part 160e may be electrically connected to each other via the connecting part 170e. The gate signal line arranged in the second pixel part 160e is divided into the first gate signal line connected to the gate drive circuit 130-1 and the second gate signal line connected to the gate drive circuit 130-2. As a result, the load on the gate signal line arranged in the second pixel part 160e can be reduced.

### Seventh Embodiment

In this embodiment, an example in which a cover member is added to the display panel 100 described in the first embodiment will be described. In this embodiment, portions different from those of the first embodiment will be described. In the drawings used in the description of this embodiment, the same components as those of the first embodiment are denoted by the same reference numerals, and detailed description thereof is omitted.

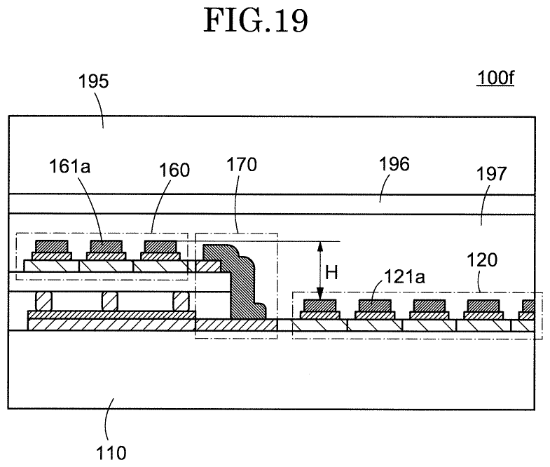

FIG. 19 is an enlarged cross-sectional view showing a configuration in a vicinity of the connecting part 170 in a display panel 100f according to a seventh embodiment. As shown in FIG. 19, the display panel 100f of this embodiment has a cover member 195 and a polarizer 196 covering the first pixel part 120 and the second pixel part 160. The cover member 195 and the polarizer 196 are adhered to the first pixel part 120 and the second pixel part 160 via an adhesive layer 197. The polarizer 196 may be provided on the main surface of the cover member 195, for example, on a surface facing the first pixel part 120 and the second pixel part 160. As the cover member 195, a substrate having a light transmittance such as a glass substrate or resin substrate can be used. In this embodiment, a resin layer having a light transmittance is used as the adhesive layer 197. By providing the polarizer 196 to the cover member 195, it is possible to block the light entering from the outside, and it is possible to improve the contrast.

The thickness of the cover member 195 is three times or more (preferably five times or more) the difference H in the height between the light-emitting surface of the first light-emitting element 121a and the light-emitting surface of the second light-emitting element 161a. The visual discomfort caused by the step between the first light-emitting element 121a and the second light-emitting element 161a can be alleviated by making the thickness of the cover member 195 sufficiently thick. By making the thickness of the cover member 195 relatively thick, the rigidity of the display panel 100f can be increased.

### Eighth Embodiment

In the display device 10 of the first embodiment, the second pixel part 160 is closer to a user than the first pixel part 120. That is, when the first light-emitting element 121a of the first pixel part 120 and the second light-emitting element 161a of the second pixel part 160 are made to emit light with the same emission intensity, the user may feel that the second light-emitting element 161a is relatively brighter. Such a difference in brightness may give the user a sense of discomfort that makes the user recognizing the border between the first pixel part 120 and the second 160.

Therefore, in this embodiment, as compared with the emission intensity of the first pixel 121 arranged in the first pixel part 120, the emission intensity of the second pixel 161 arranged in the second pixel part 160 is relatively reduced. That is, when it is made to emit light so that the user can recognize it as the same brightness, the emission intensity of the second light-emitting element 161a is reduced to be lower than the emission intensity of the first light-emitting element 121a. In this case, the rate (decay rate) at which the emission intensity is reduced is set according to the difference H (see FIG. 19) in the height between the light-emitting surface of the first light-emitting element 121a and the light-emitting surface of the second light-emitting element 161a. By reducing the emission intensity of the second light-emitting element 161a in advance at a predetermined ratio, it is possible to prevent the user from feeling uncomfortable which makes the user recognizing the border between the first pixel part 120 and the second pixel part 160.

In this embodiment, in order to reduce the emission intensity of the second light-emitting element 161a, the data signal supplied to the first data signal line 141 (see FIG. 5) may be adjusted. In this case, a pre-adjusted data signal may be output from the data drive circuit 140, or a processing circuit for converting the data signal may be provided between the data drive circuit 140 and the second pixel part 160.

### Ninth Embodiment

In the first to eighth embodiments, the display device having the light-emitting element in each pixel is exemplified, but the present invention is not limited to this example. The present invention may be applied to electronic components other than a display device. For example, the present invention can be applied to a sensor for detecting biological information or a light-emitting device for irradiating light to an object that detects biological information.

When applying the present invention to the sensor for detecting biological information, a light-receiving element that senses each pixel may be arranged. In this case, the sensor that detects biological information can perform sensing using a first light-receiving element supported by the first substrate and a second light-receiving element supported by the second substrate. The second substrate is arranged to overlap the driving circuit arranged in the first substrate. This makes it possible to provide a sensor that can effectively utilize the peripheral region where the driving circuit is arranged as a sensing region.

When the present invention is applied to a light-emitting device for irradiating light to an object that detects biological information, the light-emitting element may be arranged for each pixel. In this case, the light-emitting device can irradiate an object that detects biological information by using the first light-emitting element supported by the first substrate and the second light-emitting element supported by the second substrate. The second substrate is arranged to overlap the driving circuit arranged in the first substrate. As a result, it is possible to provide a light-emitting device that can effectively utilize the peripheral region where the driving circuit is arranged as a light-emitting region.

Each of the embodiments described above as an embodiment of the present invention can be appropriately combined and implemented as long as they do not contradict each other. Those added, deleted, changed the design of constituent elements, or added, omitted, or changed the conditions of processes by the skilled in the art are also included in the scope of the present invention as long as they have the gist of the present invention.

Even if it is other working effects which are different from the working effect brought about by the mode of each above-mentioned embodiment, what is clear from the description in this description, or what can be easily predicted by the person skilled in the art is naturally understood to be brought about by the present invention.

What is claimed is:

1. A display device comprising:
a first substrate;
a first pixel part provided on the first substrate, the first pixel part having pixels each containing a first light-emitting element;
a drive circuit provided on the first substrate, the drive circuit located adjacent to the first pixel part and connected to the first pixel part;
a second substrate;
a second pixel part provided on the second substrate, the second pixel part having pixels each containing a second light-emitting element and overlapping the drive circuit in a plan view; and
a connecting part electrically connecting the drive circuit to the second pixel part.

2. The display device according to claim 1, wherein the connecting part includes a first pad disposed between the first pixel part and the drive circuit on the first substrate, a second pad disposed adjacent to the second pixel part on the second substrate, and a conductive member electrically connecting the first pad and the second pad.

3. The display device according to claim 2, wherein the conductive member is provided on a side of the second substrate supporting the second pixel part.

4. The display device according to claim 2, wherein the conductive member is provided inside an opening in the second substrate supporting the second pixel part.

5. The display device according to claim 2, wherein the conductive member is a black member.

6. The display device according to claim 1, wherein the second pixel part has gate signal lines formed on the second substrate, and
the connecting part electrically connects the drive circuit on the first substrate to the gate signal lines on the second substrate.

7. The display device according to claim 1, wherein the first pixel part has first gate signal lines formed on the first substrate,
the second pixel part has second gate signal lines formed on the second substrate, and
the Nth (N is a natural number) gate signal line in the first gate signal lines and the Nth gate signal line in the second gate signal lines are electrically connected via the connecting part.

8. The display device according to claim 7, wherein the first gate signal lines and the second gate signal lines are connected to the drive circuit via the connecting part.

9. The display device according to claim 1, further comprising:
a shield layer disposed between the drive circuit and the second pixel part, wherein
the shield layer is formed on the first substrate and is composed of a metal material.

10. The display device according to claim 1, further comprising:
an adhesive layer disposed between the drive circuit and the second pixel part.

11. The display device according to claim 1, further comprising:
a spacer disposed between the drive circuit and the second pixel part.

12. The display device according to claim 1, wherein the first pixel part has a first light-shielding layer with an opening at a position corresponding to the first light-emitting element, and
the second pixel part has a second light-shielding layer with an opening at a position corresponding to the second light-emitting element.

13. The display device according to claim 1, wherein the second substrate is flexible and has a curved part not overlapping on the first substrate in a plan view.

14. The display device according to claim 1, wherein a thickness of the second substrate is less than ⅕ of a thickness of the first substrate.

15. The display device according to claim 1, further comprising:
a cover member covering the first pixel part and the second pixel part, and
a thickness of the cover member is five times or more than a difference in the height direction between a light emitting surface of the first light-emitting element and a light-emitting surface of the second light-emitting element.

16. A display device comprising:
a first substrate;
a first pixel part provided on the first substrate, the first pixel part having pixels each containing a first light-emitting element;
a drive circuit provided on the first substrate, the drive circuit located in the vicinity of the first pixel part;
a second substrate; and
a second pixel part provided on the second substrate, the second pixel part having pixels each containing a second light-emitting element and overlapping the drive circuit in a plan view, wherein
the first light-emitting element on the first substrate and the second light-emitting element on the second substrate are controlled based on one or more signals output from the drive circuit on the first substrate.

17. The display device according to claim 16, wherein the first pixel part has first gate signal lines formed on the first substrate,
the second pixel part has second gate signal lines formed on the second substrate, and
one or more signals output from the drive circuit is a gate signal transmitted to the first gate signal lines and the second gate signal lines.

18. The display device according to claim 17, wherein the Nth (N is a natural number) gate signal line in the first gate signal lines and the Nth gate signal line in the second gate signal lines are electrically connected to each other.

19. The display device according to claim 16, further comprising:
a shield layer disposed between the drive circuit and the second pixel part, wherein
the shield layer is formed on the first substrate and is composed of a metal material.

20. The display device according to claim 16, further comprising:
an adhesive layer disposed between the drive circuit and the second pixel part.
